(19) United States
(12) Patent Application Publication
(10) Pub. No.: US 2015/0106042 A1
(43) Pub. Date: Apr. 16, 2015

(54) COMPUTER-READABLE MEDIUM STORING ANALYSIS-SUPPORT PROGRAM, ANALYSIS SUPPORT METHOD, AND ANALYSIS SUPPORTING DEVICE

(71) Applicant: FUJITSU LIMITED, Kawasaki-shi (JP)

(72) Inventor: Shogo Fujimori, Yamato (JP)

(73) Assignee: FUJITSU LIMITED, Kawasaki-shi (JP)

(21) Appl. No.: 14/507,046

(22) Filed: Oct. 6, 2014

(30) Foreign Application Priority Data
Oct. 16, 2013 (JP) 2013-215856

(51) Int. Cl. G01R 31/28

(52) U.S. Cl. CPC G01R 31/2803
USPC 702/58

(57) ABSTRACT

A computer-readable recording medium having stored a program for an analysis-support process includes acquiring via information representing positions of a plurality of vias of a first and second via groups in a circuit board, the plurality of vias of the first and second via groups having a first and second potentials, respectively; identifying, based on the acquired via information, second via in the second via group, a first distance between the second vias and a first via in the first via group being equal to or smaller than a certain distance; identifying, based on the via information, a third via in the first via group, the third via being different from the first via, a second distance between the third via and the first via being equal to or smaller than the first distance; and generating association information that represents associations of the first, second, and third vias.

### CROSS-REFERENCE TO RELATED APPLICATION

This application is based upon and claims the benefit of priority of the prior Japanese Patent Application No. 2013-215856 filed on Oct. 16, 2013, the entire contents of which are incorporated herein by reference.

### FIELD

The embodiment discussed herein is related to a computer-readable medium storing an analysis-support program, an analysis support method, and an analysis supporting device.

### BACKGROUND

Traditionally, a technique for providing model data that represents a multi-layer circuit board to a circuit simulator and causing the circuit simulator to simulate an electromagnetic behavior of an electric conductor included in the circuit board is known (refer to, for example, Japanese Laid-open Patent Publication No. 6-325119). For example, in the model data, characteristics such as inductances and equivalent circuits of capacitors, resistors, and the like are defined and the capacitors and resistors are obtained from the shapes and positional relationships of wirings, vias, boards, terminals, parts, and the like, which are included in the multi-layer circuit board.

In addition, for a power-supply noise analysis of a multi-layer circuit, it is known a technique to generate model data representing a circuit board. The model data is generated by using effective inductances of wirings that are calculated by combining self-inductances of the wirings and mutual inductances between the wirings based on a path for a current pathway of a signal (refer to, for example, Japanese Laid-open Patent Publication No. 2011-28644).

### SUMMARY

According to an aspect of the invention, a computer-readable recording medium having stored therein a program for causing a computer to execute an analysis support process includes acquiring via information that represents positions of a plurality of vias of a first via group included in a circuit board, the plurality of vias of the first via group having a first potential and positions of a plurality of vias of a second via group included in the circuit board, the plurality of vias of the second via group having a second potential different from the first potential; identifying, based on the acquired via information, second via that is included in the plurality of vias of the second via group, a first distance between the second vias and a first via included in the plurality of vias of the first via group being equal to or smaller than a certain distance; identifying, based on the via information, a third via that is included in the first via group, the third via being different from the first via, a second distance between the third via and the first via being equal to or smaller than the first distance; and generating association information that represents associations of the first via, the second via, and the third via.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram describing an example of operations to be executed by an analysis supporting device according to an embodiment;

FIGS. 2A and 2B are diagrams illustrating an example of groups with different reference via positions;

FIG. 3 is a diagram illustrating an example of a cross-sectional image of a circuit board and model images of inductances;

FIG. 4 is a block diagram illustrating an example of a hardware configuration of the analysis supporting device according to the embodiment;

FIG. 5 is a block diagram illustrating an example of a functional configuration of the analysis supporting device;

FIGS. 6A to 6D are diagrams illustrating an example of grouping of power supply vias;

FIGS. 7A to 7D are diagrams illustrating the example of grouping of power supply vias;

FIGS. 8A to 8E are diagrams illustrating an example of grouping of GND vias;

FIG. 9 is a diagram illustrating an example of input data;

FIG. 10 is a diagram illustrating an example of an inductance matrix of power supply vias included in a group;

FIGS. 11A to 11C are diagrams describing an example of modeling;

FIG. 12 is a diagram illustrating an example of results of grouping;

FIG. 13 is a flowchart of an example of a procedure for an analysis support process to be executed by the analysis supporting device according to a first example of the embodiment;

FIG. 14 is a flowchart of an example of a procedure for a grouping process;

FIG. 15 is a flowchart of the example of the procedure for the grouping process;

FIG. 16 is a diagram illustrating an example of a cross section of the circuit board that includes a noise wave source;

FIG. 17 is a flowchart of an example of a procedure for the analysis support process to be executed by the analysis supporting device according to a second example of the embodiment; and

FIG. 18 is a flowchart of an example of a procedure for a process of generating model data.

### DESCRIPTION OF EMBODIMENTS

When the number of mutual inductances, defined by model data, between vias is increased, it takes a long time to execute analysis. In addition, when the number of the mutual inductances, defined by the model data, between the vias is reduced, the accuracy of the analysis is reduced. Accordingly, it is desired to provide an analysis support method which may improve the accuracy of analysis.

Hereinafter, embodiments for an analysis support program, an analysis support method, and an analysis supporting device are described with reference to the accompanying drawings.

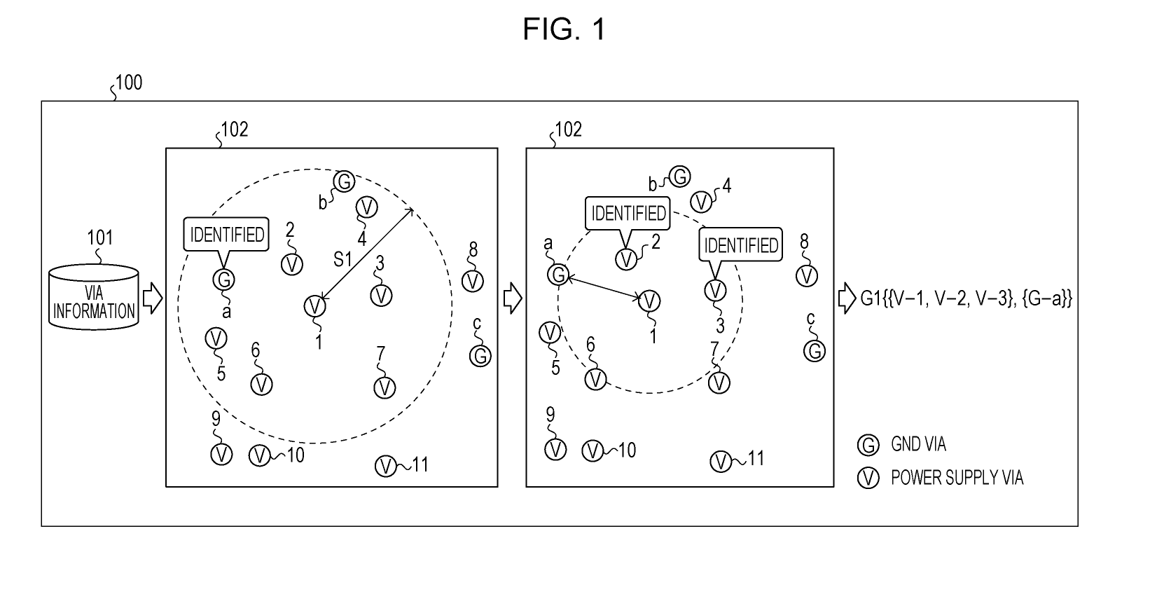

FIG. 1 is a diagram illustrating an example of operations to be executed by an analysis supporting device according to the embodiment. The analysis supporting device 100 is a computer configured to support generation of model data that is used to analyze an electromagnetic behavior of a multi-layer circuit board 102. The multi-layer circuit board 102 is, for example, a printed circuit board (PCB), a multi-chip module (MCM), a package of a semiconductor integrated circuit, or the like. For example, the model data to be generated is suitable for analysis of power supply noise of the circuit board 102. The model data is information that represents elements included in the circuit board 102 by defining characteristics of both inductances and an equivalent circuit of resistors and capacitors. Defining the characteristics of both the inductances and the equivalent circuit of the resistors and the capacitors by the model data is referred to as modeling. The model data is described in an available description format by a circuit simulator such as a Simulation Program with Integrated Circuit Emphasis (SPICE).

The analysis supporting device 100 acquires via or through hole information 101 that represents the positions of vias or through holes of a first via group, having a first potential, included in the circuit board 102 and the positions of vias or through holes of a second via group, having a second potential different from the first potential, included in the circuit board 102. In the example illustrated in FIG. 1, the first potential is a power supply potential, and the second potential is a ground (hereinafter abbreviated to GND (GROUND) in some cases) potential. The first and second potentials, however, are not limited to those potentials. The first potential may be the GND potential, and the second potential may be the power supply potential. The first via group of the power supply potential is referred to as a power supply via group, while each of the vias of the power supply via group is referred to as a power supply via V. In addition, the second via group of the GND potential is referred to as a GND via group, while each of the vias of the GND via group is referred to as a GND via G. In the example illustrated in FIG. 1, the circuit board 102 includes power supply vias V-1 to V-11 and GND vias G-a to G-c. Although the circuit board 102 includes parts such as the semiconductor integrated circuit, a power supply, a bypass capacitor, and the like, an illustration of the parts is omitted in the example illustrated in FIG. 1.

The via information 101 includes coordinate information that represents coordinates of the vias in the power supply via group and in the GND via group from a coordinate origin in design data for the circuit board 102. The via information 101 may include information to be used to determine inductance values of the vias. The information to be used to determine the inductance values is the shapes and the outlines of the vias, or the like. Examples of details of the information to be used to determine the inductance values will be described later.

The analysis supporting device 100 identifies, based on the acquired via information 101, a second via that is included the GND via group and of which a distance from a first via included in the power supply via group is equal to or smaller than a predetermined or certain distance S1. The first via may be randomly selected from among the power supply via group by the analysis supporting device 100. All the vias included in the power supply via group may be treated as the first via to group all of vias included in the power supply via group. In the example illustrated in FIG. 1, the power supply via V-1 is selected as the first via. In the example illustrated in FIG. 1, since the number of GND vias of which distances from the power supply via V-1 is equal to or smaller than the predetermined distance S1 is two or more, the analysis supporting device 100 identifies, as the second via, the GND via G-a that is closest to the power supply via V-1 among the GND vias and of which the distance from the power supply via V-1 is equal to or smaller than the predetermined distance S1.

Subsequently, the analysis supporting device 100 identifies, based on the via information 101, a third via that is included in the power supply via group and is not the first via and of which a distance from the first via is equal to or smaller than a distance between the identified second via and the first via. The analysis supporting device 100 may identify third via or vias of which distance from the first via is equal to or smaller than the distance between the identified second via and the first via. In the example illustrated in FIG. 1, as the third vias, the power supply via V-2 and the power supply via V-3 are identified.

Then, the analysis supporting device 100 generates association information that represents associations or an association among the first via, the second via, and the third via or vias. In the example illustrated in FIG. 1, as the association information, information that represents “G1{{V-1, V-2, V-3}, {G-a}}” is generated. Thus, the analysis supporting device 100 may identify that the power supply via V-1, the power supply via V-2, and the power supply via V-3 are included in a group G1, and that the GND via G-a is identified as a reference via of the group G1. Based on the association information, the analysis supporting device 100 treats the second via as the reference via and determines a self-inductance of the first via, a self-inductance of the third via, and a mutual inductance between the first via and the third via. The reference via is a via in which feedback currents from the first via and the third via flow. A specific example of the calculation will be described later. The analysis supporting device 100 generates, based on the calculated inductances, information that represents the first via and the third via. The generated information is description information in which the inductances, included in the aforementioned model data, of the vias are defined.

As described above, when mutual inductances between all vias of the same potential are modeled, the accuracy of analysis is improved, but a period of time for the analysis increases. When the mutual inductances between all the vias of the same potential are not modeled, the analysis is executed at a higher speed, but the accuracy of the analysis is reduced. Thus, the analysis is not efficiently executed. On the other hand, in the embodiment, the analysis supporting device 100 identifies a second via having the second potential and located close to a first via of the first potential and identifies a third via having the first potential and located closer to the first via than the identified second via. Thus, only a mutual inductance between power supply vias that may have the same feedback path for a passing current may be modeled. Thus, while the period of time for the analysis may be suppressed, the accuracy of the analysis may be improved.

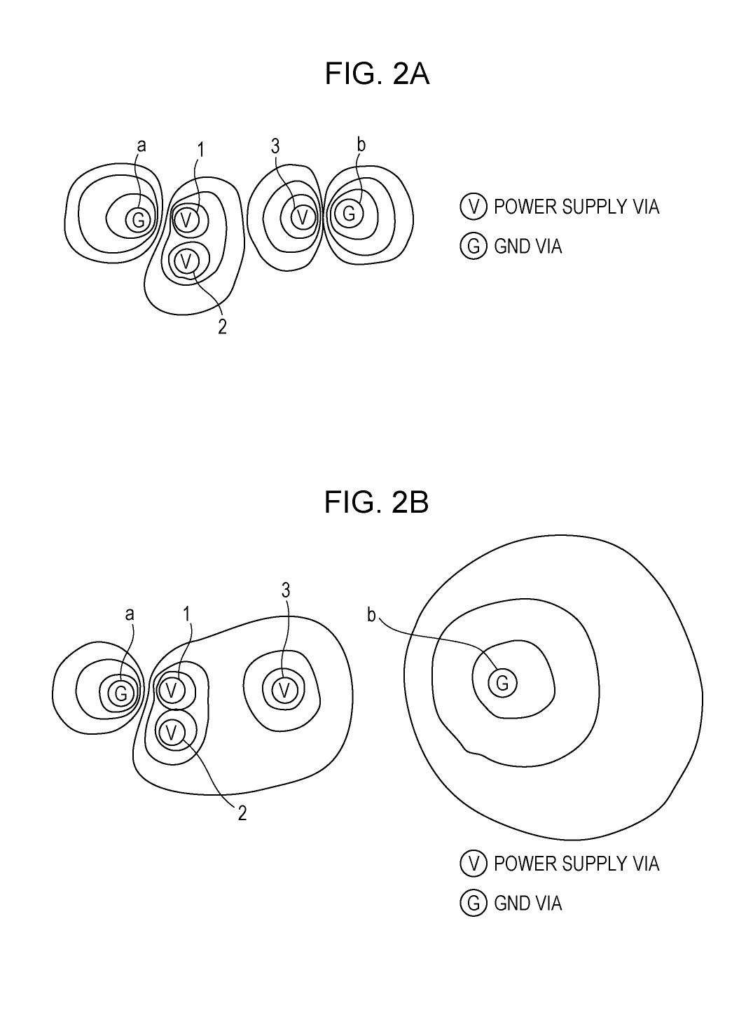

FIGS. 2A and 2B are diagrams illustrating examples of groups that are different in the position of reference vias. In the example illustrated in FIG. 2A, a reference via for the power supply via V-1 and the power supply via V-2 is the GND via G-a, and magnetic lines or lines of magnetic force generated by a current passing through the power supply via V-3 are different from magnetic lines generated by currents passing through the power supply vias V-1 and the power supply via V-2. The GND via G b illustrated in FIG. 2B is more separated from the power supply via V-3 than the GND via G b illustrated in FIG. 2A. The positions of the power supply via V-1, the power supply via V-2, and the power supply via V-3 illustrated in FIG. 2B are the same as the example illustrated in FIG. 2A, but a reference via for the power supply via V-1, the power supply via V-2, and the power supply via V-3 is the GND via G-a in the example illustrated in FIG. 2B. In addition, magnetic lines are generated by currents passing through the power supply via V-1, the power supply via V-2, and the power supply via V-3 in the example illustrated in FIG. 2B. As described with reference to FIGS. 2A and 2B, an inductance matrix to be calculated varies depending on the position of a reference via.

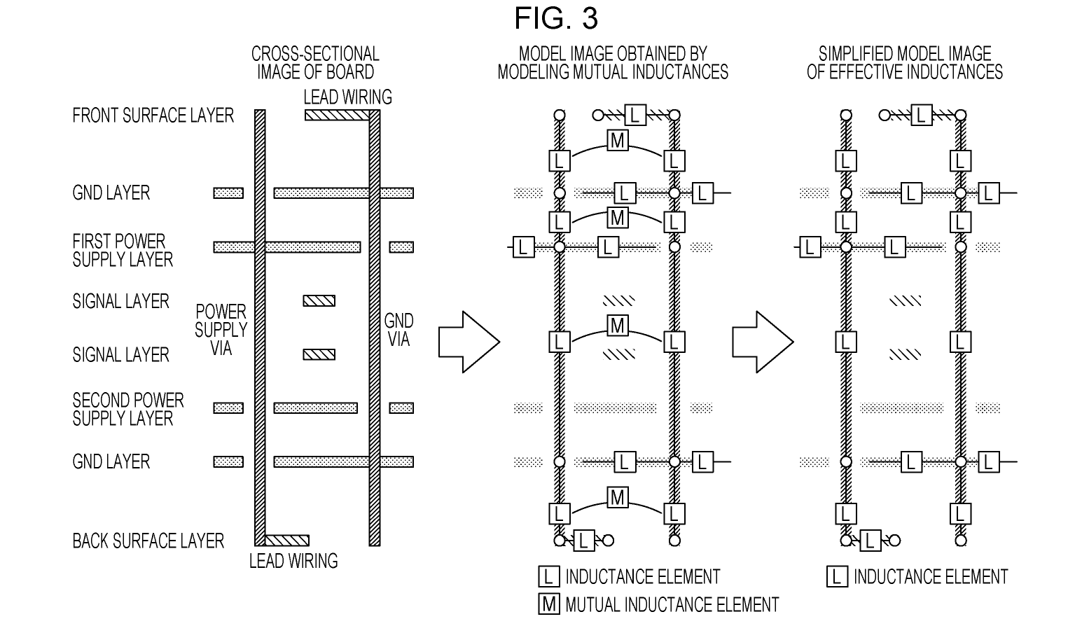

FIG. 3 is a diagram illustrating an example of schematic views of a cross-section of the circuit board and model of inductances. The schematic views are briefly described below. As illustrated in the example of schematic view of the cross section of the circuit board 102, the circuit board 102 includes a multi-layer structure including a front surface layer, a back surface layer, signal layers, GND layers, a first power supply layer, and a second power supply layer. Each of the front surface layer and the back surface layer includes wirings that serve as signal lines, each of which is coupled to a part or parts with each other. Each of the signal layers includes wirings that serve as signal lines. Each of the GND layers includes a ground plane. The first and second power supply layers include a first and second power supply planes, respectively. Although the aforementioned layers are conductive bodies, non-conductive bodies (not illustrated) are stacked between the conductive layers.

In the example illustrated in FIG. 3, the power supply vias V couple the first power supply plane included in the first power supply layer to a lead wiring included in the back surface layer. The layout of the power supply vias V is not limited to this example. The power supply vias V may couple power supply wirings included in different layers and having the power supply potential to each other, may couple the power supply planes having the power supply potential to each other, and may couple the power supply wirings having the power supply potential to the power supply planes having the power supply potential, although the connections are not illustrated.

In the example illustrated in FIG. 3, the GND vias G couple a GND plane included in the upper GND layer, a GND plane included in the lower GND layer, and a lead wiring included in the front surface layer to each other. The layout of the GND vias G is not limited to this example. For example, the GND vias G may couple ground wirings included in different layers and having the ground potential to each other, may couple the GND planes having the ground potential to each other, and may couple the ground wirings having the ground potential to the GND planes having the ground potential, although the connections are not illustrated.

As illustrated on the left side of FIG. 3, when the power supply via V and the GND via G are arranged so as to ensure that each power supply via V is located adjacent to a respective GND via G, the GND via G serves as a feedback path for a current passing through the power supply via V, and currents with almost the same amount flow between the power supply via V and the GND via G in directions opposite to each other. When each power supply via V is located adjacent to a respective GND via G, a self-inductance of the power supply via V is represented by L_{sV}, a self-inductance of the GND via G is represented by L_{sG}, and a mutual inductance between the power supply via V and the GND via G is represented by M. In this case, a schematic view of the model illustrated in a central part of FIG. 3 is obtained by modeling mutual inductances between power supply vias V and GND vias G. In addition, an effective inductance L_{effV} of the power supply via V is expressed by the following Equation (1), and an effective inductance L_{effG} of the GND via G is expressed by the following Equation (2). A schematic view of the model simplified using the effective inductances is illustrated on the right side of FIG. 3.

L_{effV}=L_{sV}−M (1)

L_{effG}=L_{sG}−M (2)

On a small board of a mobile terminal or the like, the flexibility of the arrangement of vias is low, and power supply vias V and GND vias G are arranged so that each power supply via V is not located adjacent to a respective GND via G. Thus, when mutual inductances between all vias are modeled in order to improve the accuracy of analysis, the number of elements of a model may increase and a period of time for the analysis may increase. In addition, when the mutual inductances between the vias are not modeled in order to reduce the period of time for the analysis, the number of elements of a model may be reduced, and the accuracy of the analysis may be reduced. In the embodiment, a second power supply via, of which a distance from a first power supply via is equal to or smaller than a distance between the first power supply and a GND via of which a distance from the first power supply via is equal to or smaller than the predetermined distance S1, is identified. Thus, only a mutual inductance between power supply vias that have the same feedback path for a passing current may be modeled. Thus, the accuracy of the analysis may be improved while the number of mutual inductances to be modeled is suppressed.

In addition, when each power supply via V is located adjacent to a respective GND via G, the GND via G serves as a return path for a current passing through the power supply via V, and currents with almost the same amount flow between the power supply via V and the GND via G in directions opposite to each other. In this case, the power supply via V and the GND via G may be modeled using effective inductances. In the embodiment, power supply vias V located close to each other, or GND vias G located close to each other, are grouped, inductance matrices are calculated for groups, and mutual inductances are modeled.

An analysis process procedure is briefly described below. The analysis supporting device 100 acquires implementation design data of the circuit board 102 and generates board model data of the conductive layers. For example, the implementation design data includes positional information of parts of the circuit board 102, the vias, and the wirings. Then, the analysis supporting device 100 generates board model data of the vias according to the embodiment. In addition, the analysis supporting device 100 acquires characteristic data of the parts disposed on the circuit board 102 and generates part model data that represents the parts. Then, the analysis supporting device 100 generate model data that represents the parts, boards, and connections of the boards to the parts. Then, the analysis supporting device 100 executes a circuit simulation. Although the example in which the analysis supporting device 100 executes the processes is described above, the analysis supporting device 100 is not limited to this. The analysis supporting device 100 may only generate the board model data of the vias, and the other processes may be executed by another device. Next, details of the analysis supporting device 100 will be described.

[Example of Hardware Configuration of Analysis Supporting Device 100]

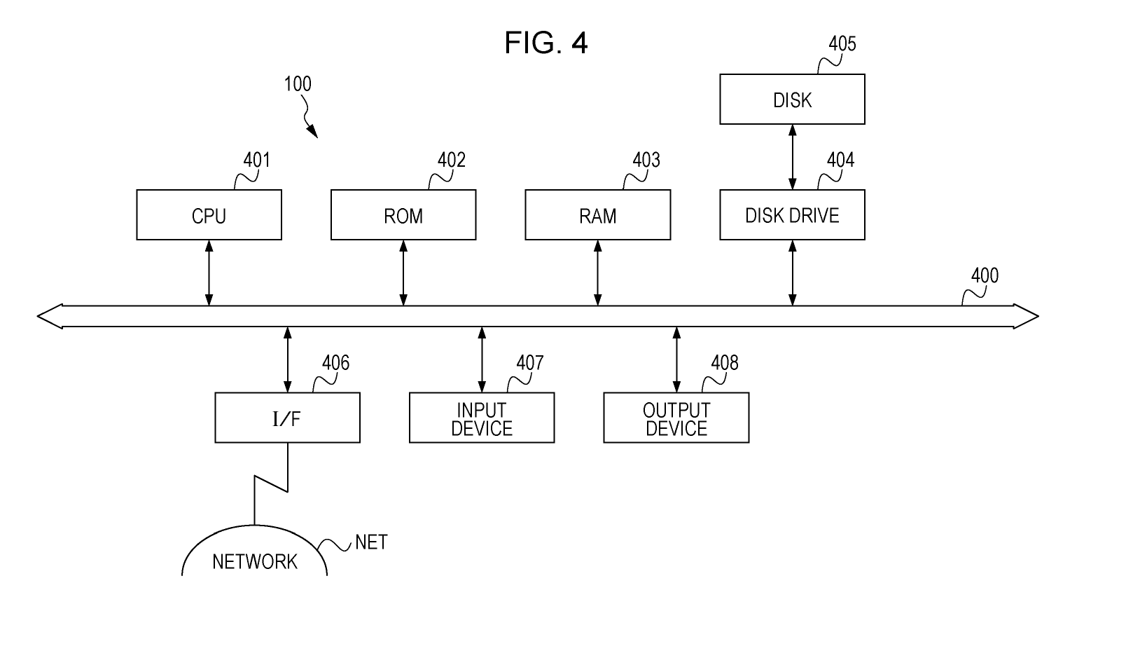

FIG. 4 is a block diagram illustrating an example of a configuration of the analysis supporting device 100 according to the embodiment. Referring to FIG. 4, the analysis supporting device 100 includes a central processing unit (CPU) 401, a read only memory (ROM) 402, a random access memory (RAM) 403, a disk drive 404, and a disk 405. The analysis supporting device 100 includes an interface (I/F) 406, an input device 407, and an output device 408. The parts 401 to 404 and 406 to 408 are coupled to each other by a bus 400.

The CPU 401 controls the overall analysis supporting device 100. The ROM 402 includes, stored therein, programs such as a boot program. The RAM 403 is used as a work area of the CPU 401. The disk drive 404 controls reading and writing of data from and in the disk 405 in accordance with control of the CPU 401. The disk 405 stores data written in accordance with control of the disk drive 404. The disk 405 is a magnetic disk, an optical disc, or the like.

The I/F 406 is coupled to a network NET such as a local area network (LAN), a wide area network (WAN), or the Internet and coupled to another device through the network NET. The I/F 406 serves as an interface between the inside of the analysis supporting device 100 and the network NET to control input and output of data to and from the other device. The I/F 406 is a modem, a LAN adapter, or the like.

The input device 407 is a keyboard, a mouse, a touch panel, or the like and is an interface configured to receive various types of data by an operation of a user. The input device 407 may receive a sound from a microphone. The output device 408 is an interface configured to output data in accordance with an instruction from the CPU 401. The output device 408 is a display, a printer, or the like.

[Example of Functional Configuration of Analysis Supporting Device 100]

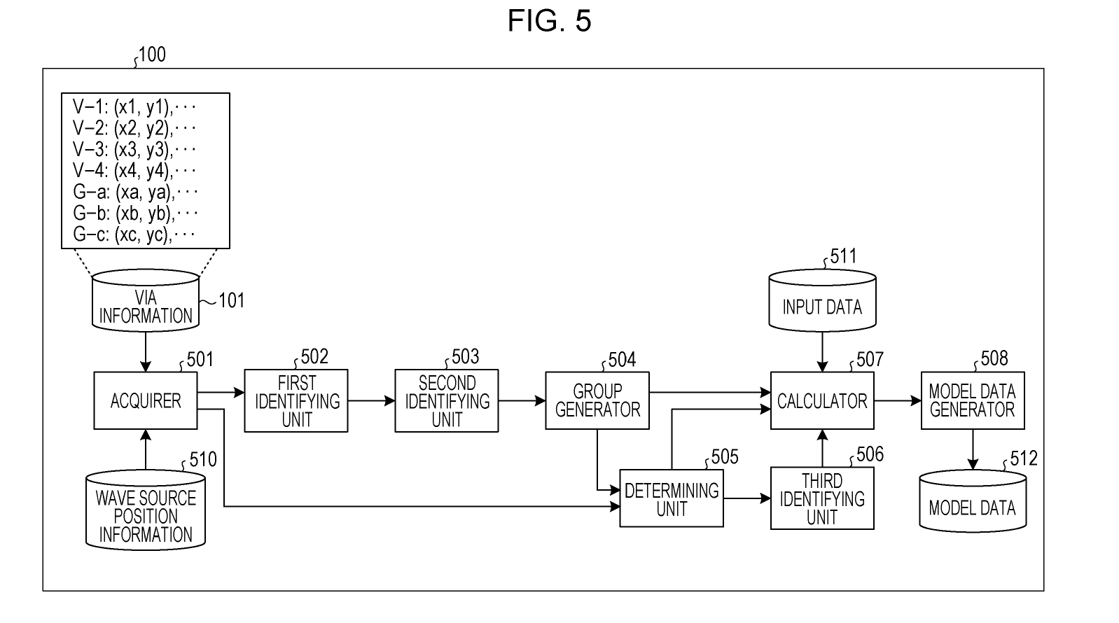

FIG. 5 is a block diagram illustrating an example of a functional configuration of the analysis supporting device 100. The analysis supporting device 100 includes functional units such as an acquirer 501, a first identifying unit 502, a second identifying unit 503, a group generator 504, a determining unit 505, a third identifying unit 506, a calculator 507, and a model data generator 508. Processes of the functional units 501 to 508 are coded into an analysis support program that is stored in a storage device such as the ROM 402 or the disk 405. The CPU 401 reads the analysis support program from the storage device and executes the processes coded into the analysis support program. In this manner, the processes of the functional units 501 to 508 are achieved. Results of the processes of the functional units 501 to 508 are stored in a storage device such as the RAM 403 or the disk 405.

The functional units will be explained in first and second examples. In the first example, a third via that has the first potential and of which a distance from a first via of the first potential is equal to or smaller than a distance between the first via and a second via that has the second potential and of which a distance from the first via is equal to or smaller than the predetermined or certain distance S1. Thus, in the first example, vias that have the first potential and have the same feedback path for a passing current may be grouped into the same group. In the second example, the number of mutual inductances defined by model data may be reduced by inhibiting a mutual inductance from being calculated for a via included in a group separated from a noise wave source.

### First Example

In the first example, a second via that has the second potential and is located close to a first via of the first potential is identified, and a third via that has the first potential and is located closer to the first via than the identified second via is identified. Thus, power supply vias that has the same feedback path for a passing current may be grouped into the same group. Thus, only a mutual inductance between power supply vias that may have the same feedback path for a passing current may be modeled. Thus, the accuracy of the analysis may be improved while the number of mutual inductances to be modeled is suppressed.

The acquirer 501 acquires the via information 101 that represents the positions of the vias of the first via group included in the circuit board 102 and having the first potential and the positions of the vias of the second via group included in the circuit board 102 and having the second potential different from the first potential. The positions of the vias are central coordinates of the vias from the coordinate origin. The acquirer 501 may acquire the via information 101 by reading the via information 101 stored in a storage device such as the disk 405. Alternatively, the acquirer 501 may acquire the via information 101 input through the input device 407 or the like or acquire the via information 101 through the I/F 406 from the other device. For example, when the first potential is the power supply potential, the second potential is the ground potential. For example, when the first potential is the ground potential, the second potential is the power supply potential. In the example illustrated in FIG. 5, information that identifies each of the power supply vias V is V-number, while information that identifies each of the GND vias G is G-alphabet. In order to easily understand the vias, the information that identifies the power supply vias V and the GND vias G is the same as reference symbols of the power supply vias V and reference symbols of the GND vias G. As described above, the via information 101 may include information that represents the shapes of the vias, the diameters of the vias, and the like and is used to calculate inductances.

The first identifying unit 502 identifies, based on the acquired via information 101, a second via that is included in the second via group and of which a distance from a first via included in the first via group is equal to or smaller than the predetermined or certain distance S1. The first identifying unit 502 sequentially selects first vias from among the first via group. The predetermined distance S1 may be arbitrarily determined by the user or set to a value that is approximately five times larger than intervals between terminals of the semiconductor integrated circuit that is included in the circuit board and is the noise wave source. Alternatively, the predetermined distance S1 may be stored in a storage device such as the disk 405 or may be entered by the user through the input device 407. The first identifying unit 502 identifies a second via that is included in the second via group and located closest to a first via and of which a distance from the first via is equal to or smaller than the predetermined distance S1. Thus, a feedback path for a current passing through the first via is identified.

The second identifying unit 503 identifies, based on the via information 101, a third via that is included in the first via group and is not the first via and of which a distance from the first via is equal to or smaller than a distance between the identified second via and the first via.

The group generator 504 generates association information that represents associations of the first via, the identified second via, and the identified third via. Specifically, in the embodiment, the group generator 504 groups the first via and the identified third via into a single group and treats the second via as a reference via of the group. Then, the group generator 504 causes the association information to be stored in a storage device such as the disk 405. For example, when the first potential is the power supply potential and the second potential is the ground potential, the group generator 504 adds the group as association information to the following power supply group string.

The power supply group string=identification information identifying groups and representing {{identification information identifying power supply vias V included in the groups}, {identification information identifying GND vias serving as reference vias}}

When the first potential is the power supply potential and the second potential is the ground potential, the group generator 504 adds the group as association information to the following GND group string.

The GND group string=identification information identifying groups and representing {{identification information identifying GND vias G included in the groups}, {identification information identifying power supply vias V serving as reference vias}}

When the third via is not identified, the group generator 504 generates association information that represents associations of the first via, the second via, and the third via. When the first potential is the power supply potential and the second potential is the ground potential, the group generator 504 adds the information to the following power supply string.

The power supply string={identification information identifying power supply vias V, identification information identifying GND vias G serving as reference vias}

When the first potential is the ground potential and the second potential is the power supply potential, the group generator 504 adds the information to the following GND string.

The GND string={identification information identifying GND vias G, identification information identifying power supply vias V serving as reference vias}

The calculator 507 calculates, based on the generated association information and the via information 101, a self-inductance of the first via, a self-inductance of the third via, and a mutual inductance between the first via and the third via. Next, the model data generator 508 generates, based on the calculated self-inductances and the calculated mutual inductance, information that represents the first via and the third via. The information that represents the first via and the third via is model data 512, for example. The model data 512 is described using an available language by SPICE or the like.

The vias included in the first via group may be selected as first vias. For example, the first identifying unit 502 sequentially selects the vias from among the first via group as the first vias. Then, the first identifying unit 502 identifies a second via for each of the first vias. The second identifying unit 503 identifies a third via for each of the first vias. The group generator 504 generates association information for each of the first vias. Thus, the grouping process may be executed on each of the vias of the first via group.

The calculator 507 calculates a self-inductance of a target via included in the first via group and to be calculated, self-inductances of first associated vias included in the first via group, and mutual inductances between the first associated vias and the target via. The first associated vias are vias included in the first via group and associated with the target via. The calculator 507 calculates the mutual inductances based on the generated association information, the via information 101, and second associated vias that are included in the second via group and are each associated with any of the target via and the detected first associated vias. The calculator 507 provides input data 511 on the vias included in a group and a reference via for the group to an application enabling an inductance matrix to be calculated and thereby obtains an inductance matrix of vias included in the group to be calculated. The application is a field solver using a finite element method or a boundary element method, for example.

Then, the model data generator 508 generates, based on the calculated self-inductances and the calculated mutual inductances, information that represents the target via and the first associated vias. Specifically, the model data generator 508 generates description data that is included in the model data 512 representing the target via and the first associated vias and is related to inductance components, for example. An example of the description data is described later as the model data 512.

When the first associated vias do not exist and the second vias associated with the target via exist, the calculator 507 calculates an effective inductance of the target via based on distances between the target via and the second associated vias. When the first potential is the power supply potential, the case in which the first associated vias do not exist means that the target via is not included in the power supply group string. When the second potential is the GND potential, the case in which the first associated vias do not exist means that the target via is not included in the GND group string. When the first potential is the power supply potential, the calculator 507 calculates a self-inductance of a power supply via V that does not belong to any group. For example, when a reference via for a via to be calculated exists, the calculator 507 calculates a self-inductance according to the following Equations (3) to (5).

$$\begin{matrix}{L}_{s} = \frac{{μ}_{0}}{2 π} \{ 1 log \frac{1 + \sqrt{{r}^{2} + {l}^{2}}}{r} - \sqrt{{r}^{2} + {l}^{2}} + r \} & ( 3 ) \\ M = \frac{{μ}_{0}}{2 π} \{ 1 log \frac{1 + \sqrt{{s}^{2} + {l}^{2}}}{s} - \sqrt{{s}^{2} + {l}^{2}} + s \} & ( 4 ) \\ {L}_{eff} = {L}_{s} - M & ( 5 )\end{matrix}$$

In Equations (3) and (4), μ₀ is the relative permeability, l is the length of the via, r is the diameter of the via, and s is a distance between the power supply via V and the GND via G. It is assumed that information of the length and diameter of the via is stored in a storage device such as the disk or entered by the user through the input device. When the second associated vias do not exist, the calculator 507 calculates an effective inductance of the target via. Specifically, when a reference via for the target via to be calculated does not exist, the calculator 507 calculates the self-inductance according to the following Equation (6).

L_{eff}=Lₛ (6)

The model data generator 508 generates, based on the effective inductance L_{eff} calculated by using the Equation (6), information that represents the target via.

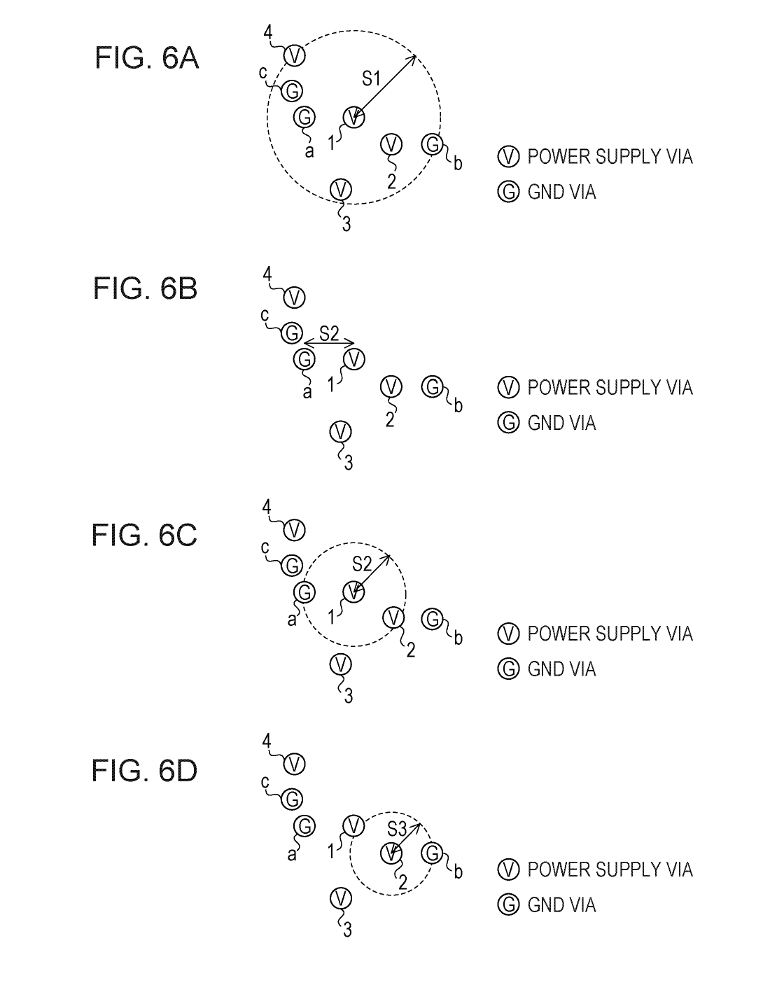

Based on the above description, the process of grouping the power supply vias V and the GND vias G by the first identifying unit 502, second identifying unit 503, and group generator 503 of the analysis supporting device 100 is described in detail with reference to FIGS. 6A to 8E.

FIGS. 6A to 6D are diagrams illustrating an example of the process of grouping power supply vias. In the example illustrated in FIGS. 6A to 6D, the power supply vias V-1 to V-4 and the GND vias G-a to G-c are arranged in a via layer included in the circuit board 102. First, the analysis supporting device 100 selects the power supply via V-1 as a first via. Then, as illustrated in FIG. 6A, the analysis supporting device 100 identifies a second via that is located closest to the power supply via V-1 among GND vias V and of which a distance from the power supply via V-1 is equal to or smaller than the predetermined distance S1. In the example illustrated in FIGS. 6A to 6D, the GND vias G of which distances from the power supply via V-1 are equal to or smaller than the predetermined distance S1 are the GND vias G-a, G-b, and G-c, and the analysis supporting device 100 identifies the GND via G-a as the second via.

As illustrated in FIG. 6B, the analysis supporting device 100 calculates a distance S2 between the position of the power supply via V-1 and the position of the identified GND via G-a. Then, as illustrated in FIG. 6C, the analysis supporting device 100 identifies a third via of which a distance from the power supply via V-1 is equal to or smaller than the calculated distance S2. In the example illustrated in FIGS. 6A to 6D, the analysis supporting device 100 identifies the power supply via V-2 as the third via. In the example illustrated in FIGS. 6A to 6D, the number of third vias is 1. When multiple third vias of which distances from the power supply via V-1 are equal to or smaller than the calculated distance S2 exist, the analysis supporting device 100 may identify the multiple third vias. The analysis supporting device 100 determines, based on the power supply group string, whether or not each of the power supply via V-1 and the power supply via V-2 belongs to any group. In the example illustrated in FIGS. 6A to 6D, each of the power supply via V-1 and the power supply via V-2 does not belong to any group, and thus the analysis supporting device 100 newly generates information identifying a group. Then, the analysis supporting device 100 adds the group to the power supply group string. Thus, the power supply group string is represented as follows. Reference symbols of the vias are used as information identifying the vias.

The power supply group string=GV1{{V-1, V-2}, {G-a}}

Next, as illustrated in FIG. 6D, the analysis supporting device 100 selects the power supply via V-2 as a first via from among the power supply vias V. A description of a process to be executed by the analysis supporting device 100 after a state illustrated in FIG. 6D is simplified. As illustrated in FIG. 6D, the analysis supporting device 100 identifies, from the GND vias G, the GND via G-b that is closest to the power supply via V-2 and of which a distance from the power supply via V-2 is equal to or smaller than the predetermined distance S1. Then, as illustrated in FIG. 6D, the analysis supporting device 100 identifies that a power supply via V of which a distance from the power supply via V-2 is equal to or smaller than a distance S3 between the power supply via V-2 and the GND via G-b does not exist. The analysis supporting device 100 determines, based on the power supply group string, whether or not the power supply via V-2 belongs to any group. Since the power supply via V-2 belongs to the aforementioned group GV1, the analysis supporting device 100 newly adds the GND via G-b to the group GV1 as a reference via of the group GV1. Thus, the power supply string is represented as follows.

The power supply group string=GV1 {{V-1, V-2}, {G-a, G-b}}

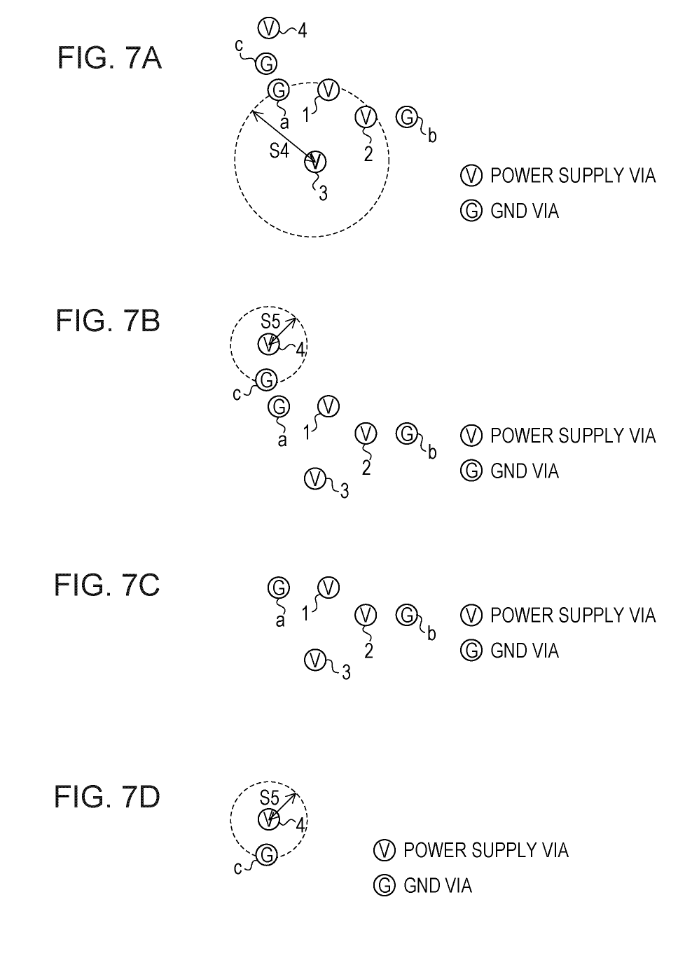

FIGS. 7A to 7D are diagrams illustrating the example of the process of grouping power supply vias. Next, as illustrated in FIG. 7A, the analysis supporting device 100 selects the power supply via V-3 as a first via from among the power supply vias V. Then, as illustrated in FIG. 7A, the analysis supporting device 100 identifies, from the GND vias G, the GND via G-a that is closest to the power supply via V-3 and of which a distance from the power supply via V-3 is equal to or smaller than the predetermined distance S1. Then, as illustrated in FIG. 7A, the analysis supporting device 100 identifies, from the power supply vias V, the power supply vias V-1 and V-2 of which distances from the power supply via V-3 are equal to or smaller than a distance S4 between the power supply via V-3 and the GND via G-a. The analysis supporting device 100 determines, based on the power supply group string, whether or not each of the power supply vias V-1, V-2, and V-3 belongs to any group. In this example, the power supply vias V-1 and V-2 belong to the group GV1. Thus, the analysis supporting device 100 newly adds the power supply via V-3 to the group GV1. Thus, the power supply group string is represented as follows.

The power supply group string=GV1 {{V-1, V-2, V-3}, {G-a, G-b}}

Next, as illustrated in FIG. 7B, the analysis supporting device 100 selects the power supply via V-4 as a first via from among the power supply vias V. As illustrated in FIG. 7B, the analysis supporting device 100 identifies the GND via G-c that is closest to the power supply via V-4 and of which a distance from the power supply via V-4 is equal to or smaller than the predetermined distance S1. Then, as illustrated in FIG. 7B, the analysis supporting device 100 identifies that a power supply via V of which a distance from the power supply via V-4 is equal to or smaller than a distance S5 between the power supply via V-4 and the GND via G-c does not exist among the power supply vias V other than the power supply via V-4. The analysis supporting device 100 determines, based on the power supply group string, whether or not the power supply via V-4 belongs to any group. The analysis supporting device 100 determines that the power supply via V-4 does not belong to any group. Then, the analysis supporting device 100 associates the GND via G-c with the power supply via V-4 and outputs information representing the association of the GND via G-c with the power supply via V-4. For example, the analysis supporting device 100 associates the GND via G-c with the power supply via V-4 as represented by the following power supply string.

The power supply string={V-4, G-c}

Next, as illustrated in FIG. 7C, the analysis supporting device 100 uses the field solver to calculate an inductance matrix of the power supply vias V included in the group GV1. Specifically, the analysis supporting device 100 treats the power supply vias V-1, V-2, and V-3 as solid cylindrical conductive bodies and treats the GND vias G-a and G-b as solid cylindrical reference conductive bodies. Then, the analysis supporting device 100 uses the field solver to calculate the inductance matrix while assuming that the shapes of the vias illustrated in FIG. 7C infinitely extend in a depth direction. A specific example is described later.

Then, as illustrated in FIG. 7D, the analysis supporting device 100 calculates a self-inductance of the power supply via V-4 according to the aforementioned Equations (3) to (5) based on the diameter of the power supply via V-4 and the third distance S5, while the power supply via V-4 does not belong to any group.

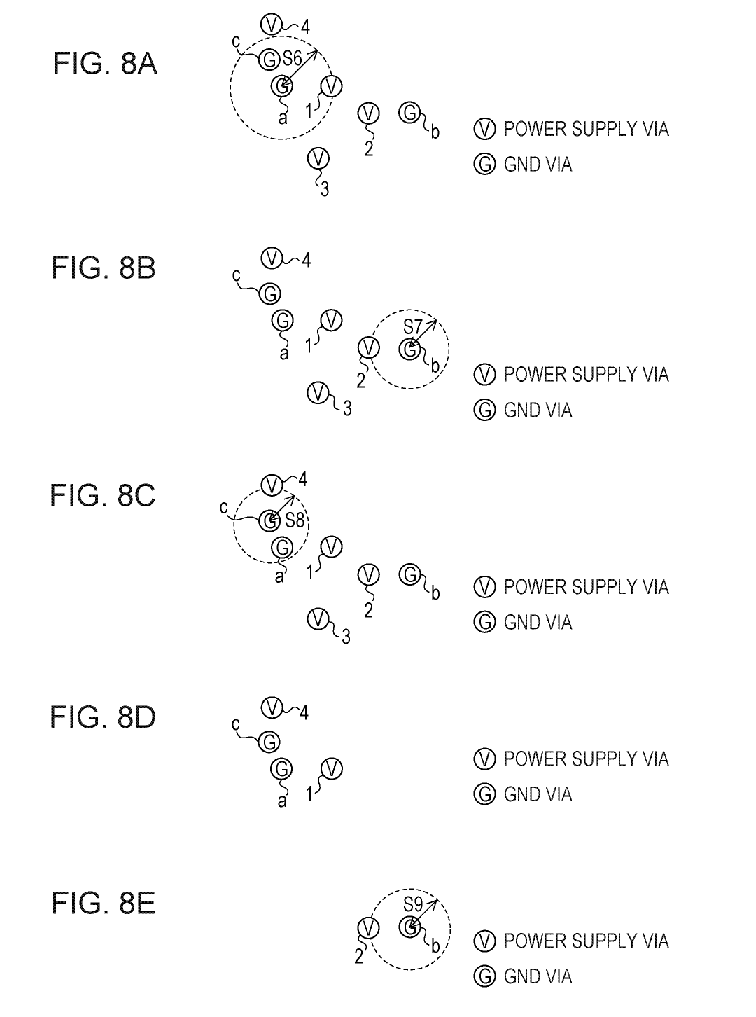

FIGS. 8A to 8E are diagrams illustrating an example of the process of grouping GND vias. In the example illustrated in FIGS. 8A to 8E, the GND vias G have the first potential, and the power supply vias V have the second potential. The example illustrated in FIGS. 8A to 8E is different from the examples illustrated in FIGS. 6A to 6D and 7A to 7D in only via group to be subjected to the grouping process. Thus, a description of the grouping process to be executed by the analysis supporting device 100 is simplified. First, as illustrated in FIG. 8A, the analysis supporting device 100 selects the GND via G-a as a first via. As illustrated in FIG. 8A, the analysis supporting device 100 identifies the power supply via V-1 that is among power supply vias V separated by the predetermined distance S1 or less from the GND via G-a and is located closest to the GND via G-a. Then, as illustrated in FIG. 8A, the analysis supporting device 100 identifies the GND via G-c that is among the GND vias G other than the GND via G-a and of which a distance from the GND via G-a is equal to or smaller than a third distance S6 between the GND via G-a and the power supply via V-1. Then, the analysis supporting device 100 determines, based on the GND group string, whether or not each of the GND vias G-a and G-c belongs to any group. In this example, each of the GND vias G-a and G-c does not belong to any group, and the analysis supporting device 100 newly generates information identifying a group. Then, the analysis supporting device 100 newly adds the group to the GND group string. Thus, the GND group string is represented as follows.

The GND group string=GG1 {{G-a, G-c}, {V-1}}

Next, as illustrated in FIG. 8B, the analysis supporting device 100 selects the GND via G-b as a first via. As illustrated in FIG. 8B, the analysis supporting device 100 identifies the power supply via V-2 that is closest to the GND via G-b and of which a distance from the GND via G-b is equal to or smaller than the predetermined distance S1. Then, as illustrated in FIG. 8B, the analysis supporting device 100 identifies that a GND via G of which a distance from the GND via G-b is equal to or smaller than a distance S7 between the GND via G-b and the power supply via V-2 does not exist among the GND vias G other than the GND via G-b. The analysis supporting device 100 determines, based on the GND group string, whether or not the GND via G-b belongs to any group. The analysis supporting device 100 determines that the GND via G-b does not belong to any group. Then, the analysis supporting device 100 associates the GND via G-b with the power supply via V-2 and outputs information of the association of the GND via G-b with the power supply via V-2. For example, the analysis supporting device 100 associates the GND via G-b with the power supply via V-2 as represented by the following GND string.

The GND string={G-b, V-2}

Next, as illustrated in FIG. 8C, the analysis supporting device 100 selects the GND via G-c as a first via. As illustrated in FIG. 8C, the analysis supporting device 100 identifies the power supply via V-4 that is located closest to the GND via G-c among power supply vias V of which distances from the GND via G-c are equal to or smaller than the first predetermined distance S1. Then, as illustrated in FIG. 8C, the analysis supporting device 100 identifies the GND via G-a that is among the GND vias G other than the GND via G-c and of which a distance from the GND via G-c is equal to or smaller than a distance S8 between the GND via G-c and the power supply via V-4. Then, the analysis supporting device 100 determines, based on the GND group string, whether or not each of the GND vias G-a and G-c belongs to any group. Since the GND vias G-a and G-c belong to the aforementioned group GG1, the analysis supporting device 100 newly adds the power supply via V-4 to the group GG1 as a reference via of the group GG1. Thus, the GND group string is represented as follows.

The GND group string=GG1 {{G-a, G-c}, {V-1, V-4}}

Next, as illustrated in FIG. 8D, the analysis supporting device 100 uses the field solver to calculate an inductance matrix of the GND vias G included in the group GG1. Specifically, the analysis supporting device 100 treats the GND vias G-a and G-c as solid cylindrical conductive bodies and treats the power supply vias V-1 and V-4 as solid cylindrical reference conductive bodies. Then, the analysis supporting device 100 uses the field solver to calculate the inductance matrix while assuming that the shapes of the vias infinitely extend in a depth direction.

Then, as illustrated in FIG. 8E, the analysis supporting device 100 calculates a self-inductance of the GND via G-b according to the aforementioned Equations (3) to (5) based on the diameter of the via and the third distance S9, while the GND via G-b does not belong to any group.

Next, an example of calculation of an inductance matrix and a detailed example of the inductance matrix are described.

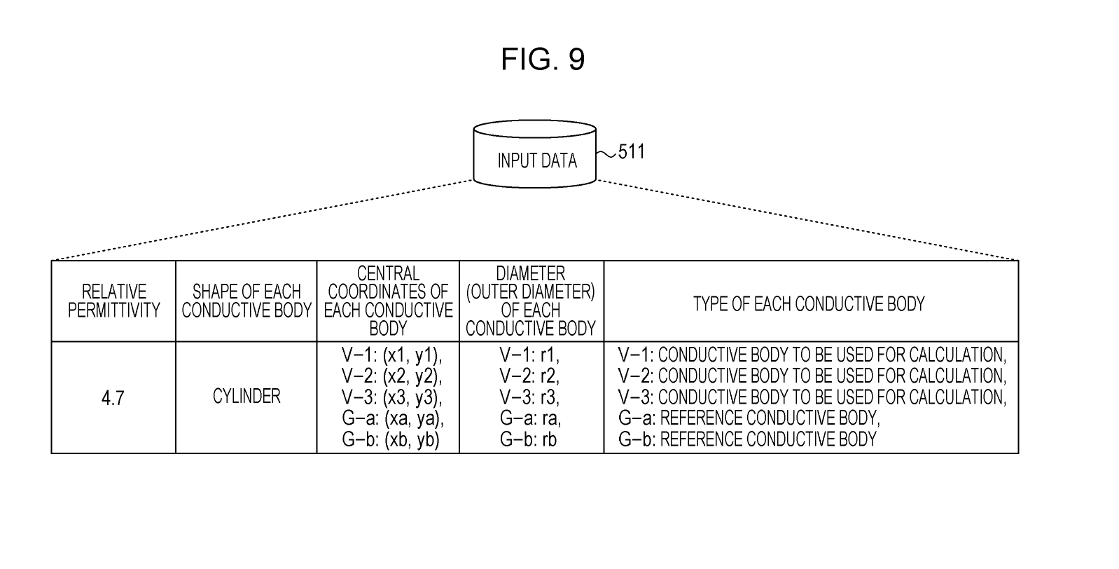

FIG. 9 is a diagram illustrating an example of the input data. The input data 511 is an example of information to be provided to the field solver when an inductance matrix of vias belonging to each group is to be calculated using the field solver. The input data 511 includes fields for a relative permittivity, the shapes of conductive bodies, central coordinates of the conductive bodies, the diameters of the conductive bodies, and the types of the conductive bodies. In FIG. 9, the group GV1 is used as an example.

In the field for the relative permittivity, the relative permittivity of a dielectric body surrounding the conductive bodies is set. The relative permittivity is a value determined based on the circuit board 102 and is assumed to be set in advance by the user or the like. For example, the relative permittivity is 4.7. In the field for the shapes of the conductive bodies, the shapes of the vias are set. In the example illustrated in FIG. 9, the shapes of the vias are a cylinder. In the field for the central coordinates of the conductive bodies, the central coordinates of the vias from the coordinate origin are set. For example, the position of the power supply via V-1 is expressed by (x1, y1).

In the field for the diameters of the conductive bodies, the outer diameters of the vias are set. For example, the outer diameter of the power supply via V-1 is r1. In the field for the types of the conductive bodies, whether each of the conductive bodies is a conductive body to be used to for the calculation of the inductance matrix or a reference conductive body is set. Since the group GV1 is used as the example, the power supply vias V-1, V-2, and V-3 are conductive bodies to be used for the calculation, and the GND vias G-a and G-b are reference conductive bodies

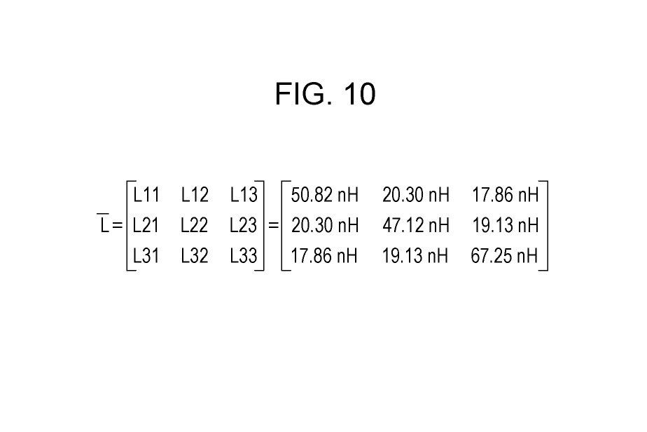

FIG. 10 is a diagram illustrating an example of an inductance matrix of power supply vias included in a group. For example, L11, L22, and L33 represent a self-inductance of the power supply via V-1, a self-inductance of the power supply via V-2, and a self-inductance of the power supply via V-3, respectively. For example, L12 and L21 represent a mutual inductance between the power supply vias V-1 and V2. For example, L13 and L31 represent a mutual inductance between the power supply vias V-1 and V-3. For example, L23 and L32 represent a mutual inductance between the power supply vias V-2 and V-3.

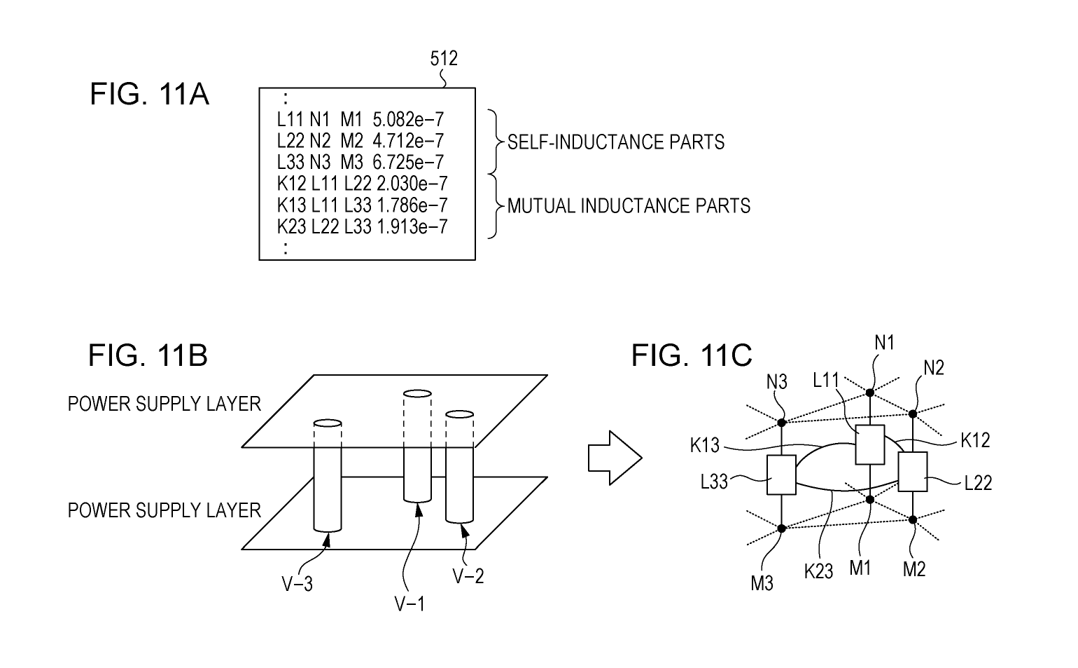

FIGS. 11A to 11C are diagrams illustrating an example of the modeling. FIG. 11A illustrates an example of the model data 512. FIG. 11B illustrates an example of a physical image of the power supply vias V-1, V-2, and V-3 connecting wirings of the two power supply layers to each other. FIG. 11C illustrates an example of an image obtained by modeling the power supply vias V-1, V-2, and V-3.

In FIG. 11C, dotted lines represent models of the planes of the power supply layers. In FIG. 11C, N1, N2, N3, M1, M2, and M3 represent connection nodes that connect planes of power supply models to via models. Thus, in FIG. 11A, the self-inductance L11 connects the connection node N1 and the connection node M1 to each other. The self-inductance L22 connects the connection node N2 and the connection node M2 to each other. The self-inductance L33 connects the connection node N3 and the connection node M3 to each other.

In FIG. 11C, a mutual inductance K12 exists between the self-inductance L11 and the self-inductance L22. In FIG. 11C, a mutual inductance K13 connects the self-inductance L11 and the self-inductance L33 to each other. In FIG. 11C, a mutual inductance K23 connects the self-inductance L22 and the self-inductance L33 to each other. The model data 512 illustrated in FIG. 11A represents that the mutual inductance K12 connects the self-inductance L11 and the self-inductance L22 to each other. The model data 512 illustrated in FIG. 11A represents that the mutual inductance K13 connects the self-inductance L11 and the self-inductance L33 to each other. The model data 512 illustrated in FIG. 11A represents that the mutual inductance K23 connects the self-inductance L22 and the self-inductance L33 to each other.

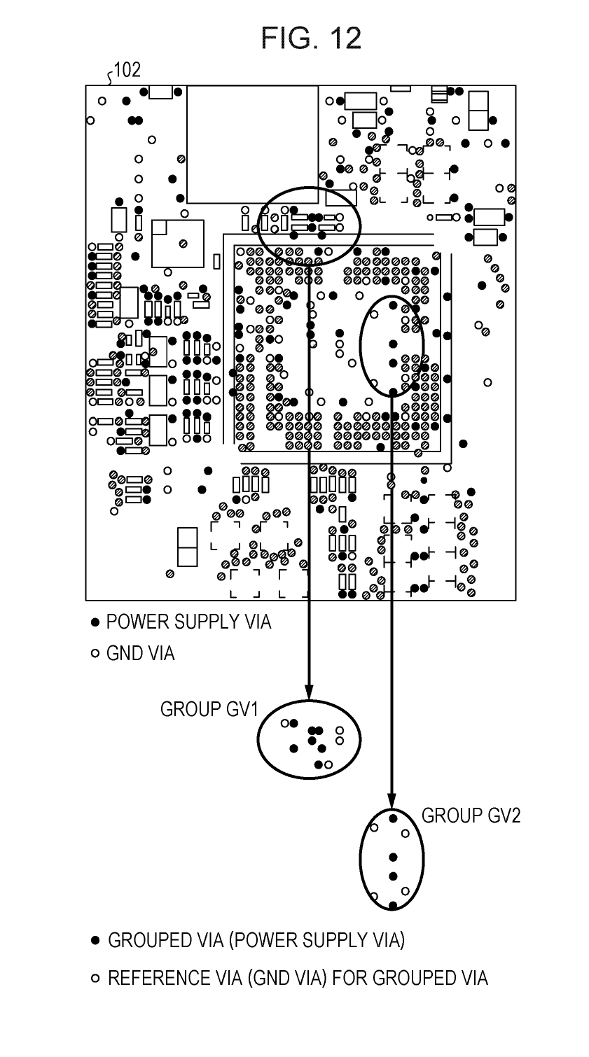

FIG. 12 is a diagram illustrating an example of results of the grouping. An upper side of FIG. 12 illustrates the circuit board 102 viewed from above. As illustrated on the upper side of FIG. 12, power supply vias are grouped into a group GV1 and a group GV2. For example, a lower side of FIG. 12 illustrates an example in which the grouped power supply vias V and reference vias for the grouped power supply vias V are extracted.

Example of Procedure for Analysis Support Process to be Executed by Analysis Supporting Device 100 According to First Example

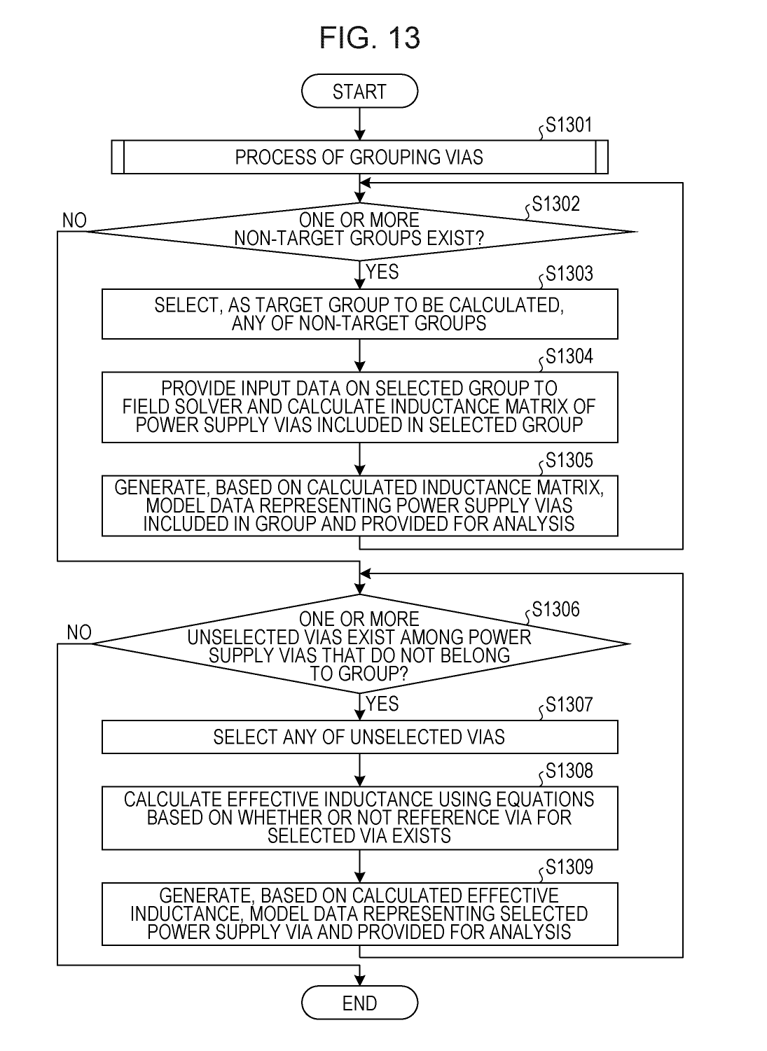

FIG. 13 is a flowchart of an example of a procedure for an analysis support process to be executed by the analysis supporting device 100 according to a first example. In the example illustrated in FIG. 13, vias of the power supply via group are to be grouped, and vias of the GND via group are treated as reference vias. When the vias of the GND via group are to be grouped and the vias of the power supply via group are to be treated as reference vias, it is sufficient when the power supply vias V are interpreted as the GND vias G in the procedure, and the GND vias G are interpreted as the power supply vias V in the procedure. First, the analysis supporting device 100 executes the process of grouping the vias (in step S1301). The analysis supporting device 100 determines whether or not one or more non-target groups exist (in step S1302). For example, the analysis supporting device 100 determines whether or not one or more unselected groups that are included in the aforementioned power supply group string and the like exist. When the analysis supporting device 100 determines that the one or more non-target groups exist (Yes in step S1302), the analysis supporting device 100 selects, as a target group to be calculated, any of the one or more non-target groups (in step S1303).

Next, the analysis supporting device 100 provides input data 511 on the selected group to the field solver and calculates an inductance matrix of power supply vias included in the selected group (in step S1304). The analysis supporting device 100 generates, based on the calculated inductance matrix, model data 512 representing the power supply vias included in the group and provided for analysis (in step S1305) and causes the process to return to step S1302.

When the analysis supporting device 100 determines that a non-target group does not exist (No in step S1302), the analysis supporting device 100 determines whether or not one or more unselected vias exist among power supply vias that do not belong to any group (in step S1306). When the analysis supporting device 100 determines that the one or more unselected vias exist (Yes in step S1306), the analysis supporting device 100 selects any of the unselected vias (in step S1307). The analysis supporting device 100 calculates an effective inductance according to the equations based on whether or not a reference via for the selected via exists (in step S1308). The equations used in step S1308 are the aforementioned Equations (3) to (6). Then, the analysis supporting device 100 generates, based on the calculated effective inductance, model data 512 representing the selected via and provided for the analysis (in step S1309) and causes the process to return to step S1306. When the analysis supporting device 100 determines that an unselected via does not exist (No in step S1306), the analysis supporting device 100 terminates the process.

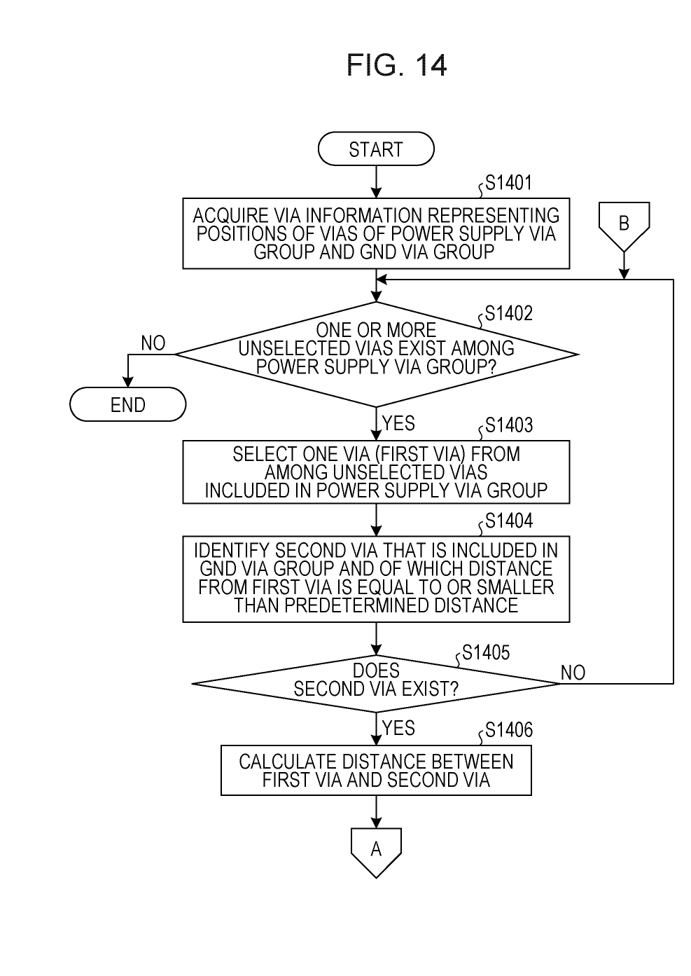

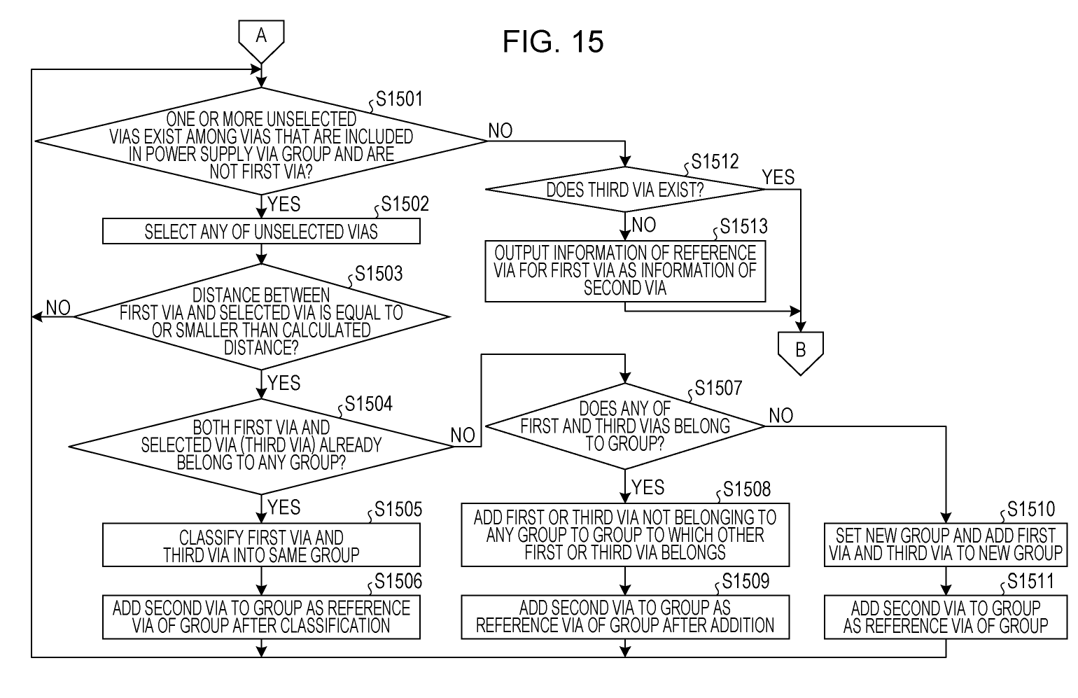

FIGS. 14 and 15 are flowcharts of an example of a procedure for the grouping process. The analysis supporting device 100 acquires the via information 101 representing the positions of the vias of the power supply via group and the positions of the vias of the GND via group (in step S1401). The analysis supporting device 100 determines whether or not one or more unselected vias exist among the power supply via group (in step S1402). When the one or more unselected vias exist (Yes in step S1402), the analysis supporting device 100 selects one via (first via) from among the unselected vias among the power supply via group (in step S1403).

The analysis supporting device 100 identifies a second via of which a distance from the first via is equal to or smaller than the predetermined distance S1 and that is included in the GND via group and located closest to the first via (in step S1404). The analysis supporting device 100 determines whether or not the second via exists (in step S1405). When the analysis supporting device 100 determines that the second via does not exist (No in step S1405), the process returns to the step S1402. When the analysis supporting device 100 determines that the second via exists (Yes in step S1405), the analysis supporting device 100 calculates a distance between the first via and the second via. The analysis supporting device 100 determines whether or not one or more unselected vias exist among vias that are included in the power supply via group and are not the first via (in step S1501).

The analysis supporting device 100 determines that the one or more unselected vias exist (Yes in step S1501), the analysis supporting device 100 selects any of the unselected vias (in step S1502). The analysis supporting device 100 determines whether or not a distance between the first via and the selected via is equal to or smaller than the calculated distance (in step S1503). When the analysis supporting device 100 determines that the distance between the first via and the selected via is not equal to or smaller than the calculated distance (No in step S1503), the analysis supporting device 100 causes the process to return to step S1501. When the analysis supporting device 100 determines that the distance between the first via and the selected via is equal to or smaller than the calculated distance (Yes in step S1503), the analysis supporting device 100 determines whether or not the first via and the selected via (third via) both already belong to any group (in step S1504). For example, the analysis supporting device 100 determines, based on information identifying the first via and information identifying the third via, whether or not the first via and the third via are both included in any of groups represented by the power supply group string.

When the analysis supporting device 100 determines that the first via and the third via both already belong to any group (Yes in step S1504), the analysis supporting device 100 classifies the first via and the third via into the same group (in step S1505). Specifically, the analysis supporting device 100 classifies a group to which the first via belongs and a group to which the third via belongs into the same group. Then, the analysis supporting device 100 adds the second via to the group as a reference via of the group after the classification (in step S1506) and causes the process to return to step S1501. When the analysis supporting device 100 determines that at least one of the first via and the third via does not belong to any group (No in step S1504), the analysis supporting device 100 determines whether or not any of the first via and the third via belongs to any group (in step S1507). When the analysis supporting device 100 determines that any of the first via and the third via belongs to any group (Yes in step S1507), the analysis supporting device 100 adds the first or third via to a group to which the other first or third via belongs (in step S1508). Then, the analysis supporting device 100 adds the second via to the group as a reference via of the group after the addition (in step S1509) and causes the process to return to step S1501. In addition, when a reference via for the first or third via not belonging to any group is already identified in step S1508, the analysis supporting device 100 adds the reference via for the first or third via to the group as a reference via of the group after the addition. This addition of the reference via is not described in FIG. 15.

When the analysis supporting device 100 determines that both first and third vias do not belong to any group (No in step S1507), the analysis supporting device 100 sets a new group and adds the first via and the third via to the new group (in step S1510). Then, the analysis supporting device 100 adds the second via to the group as a reference via of the group (in step S1511) and causes the process to return to step S1501. When a reference via for the third via is already identified, the analysis supporting device 100 adds the reference via for the third via to the group as a reference via of the group after the addition. This addition of the reference via is not described in FIG. 15.

When the analysis supporting device 100 determines that an unselected via does not exist (No in step S1501), the analysis supporting device 100 determines whether or not a third via exists (in step S1512). When the analysis supporting device 100 determines that the third via does not exist (No in step S1512), the analysis supporting device 100 outputs information of a reference via for the first via as information of a second via (in step S1513) and causes the process to return to step S1402. When the analysis supporting device 100 determines that the third via exists (Yes in step S1512), the analysis supporting device 100 causes the process to return to step S1402.

When the analysis supporting device 100 determines that an unselected via does not exist (No in step S1402), the analysis supporting device 100 terminates the process.

### Second Example

Regarding characteristics of the board with respect to a noise wave source, an inductance component in a region up to the bypass capacitor is dominant. Even when a via located far from the noise wave source is not modeled using a mutual inductance, an effect of the via on the accuracy of analyzing noise is small. In the second example, the number of elements in a model may be reduced by treating, as an inductance, a via included in a group located far from the noise wave source. In the second example, processes that are different from the first example are described, and a detailed description of the same processes as the first example is omitted.

The acquirer 501 acquires wave source position information 510 that represents the position of the noise wave source included in the circuit board 102. The determining unit 505 determines, based on the generated association information, the via information 101, and the wave source position information 510, whether or not at least any of distances from the noise wave source to a target via and first associated vias is equal to or smaller than a second predetermined distance. The noise wave source is, for example, a part such as the semiconductor integrated circuit included in the circuit board 102.

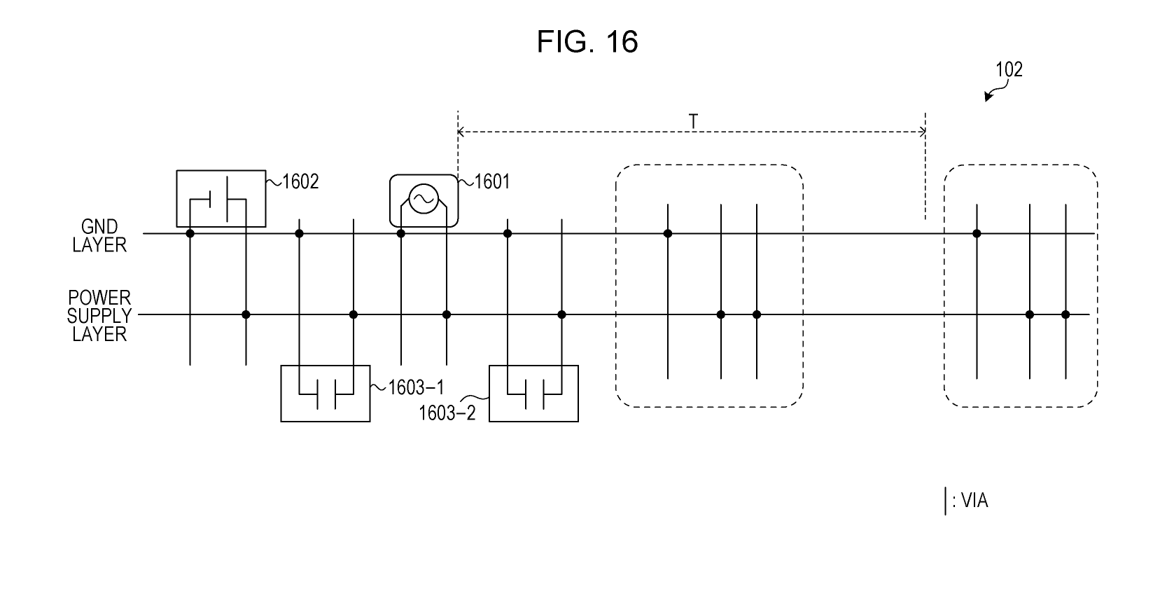

FIG. 16 is a diagram illustrating an example of a cross section of the circuit board that includes the noise wave source. In the example illustrated in FIG. 16, layers included in the circuit board 102 are illustrated in a simplified manner. In the example of the circuit board 102, the noise wave source that is a semiconductor integrated circuit 1601 is included in a front surface layer, a bypass capacitor 1603 is included in a back surface layer, and a power supply 1602 is included in the front surface layer.

When the noise wave source is the semiconductor integrated circuit 1601, the distances from the noise wave source to the target via and the first associated vias are distances from a region surrounding terminals of the semiconductor integrated circuit to the target via and the first associated vias. The second predetermined distance T may be stored in a storage device such as the disk 405 or entered by the user through the input device 407. For example, when the bypass capacitor is separated by approximately 5 mm or less from the semiconductor integrated circuit in the multi-layer board, the second predetermined distance T is may be approximately three times longer than the distance of 5 mm or less, or approximately 15 mm. The second predetermined distance T may be determined by the user based on the arrangement of the bypass capacitor.

In the example illustrated in FIG. 16, distances between the semiconductor integrated circuit 1601 and power supply vias V belonging to a group GV1 are equal to or smaller than the second predetermined distance T, and distances between the semiconductor integrated circuit 1601 and power supply vias V belonging to a group GV2 are not equal to or smaller than the second predetermined distance T.

When the determining unit 505 determines that the distances between the semiconductor integrated circuit 1601 and vias included in a group are not equal to or smaller than the second predetermined distance T, the calculator 507 does not calculate an inductance matrix of the vias included in the group. When the determining unit 505 determines that any of the distances between the semiconductor integrated circuit 1601 and the vias included in the group is equal to or smaller than the second predetermined distance T, the calculator 507 calculates the inductance matrix of the vias included in the group.

The third identifying unit 506 identifies, based on the acquired via information 101, a via that is included in the second via group and located closest to each of the target via and the first associated vias. Then, the calculator 507 calculates, based on distances from the identified vias to the target via and the first associated vias, an effective inductance of each of the target via and the first associated vias.

Then, the model data generator 508 generates, based on the smallest effective inductance among the calculated effective inductances, information that represents the target via and the first associated vias. Thus, a magnetic field that surrounds an outer side of multiple vias is dominant, and approximation may be executed based on an effective inductance of a single via. When effective inductances are modeled for the number of vias in parallel without modeling using a mutual inductance, the inductances are smaller than actual inductances. Thus, the accuracy of the analysis may be further improved by modeling only an effective inductance of a single via. The generated information is description data that is included in the model data 512 representing the target via and the first associated vias and is related to the effective inductances. The generated result is stored in a storage device such as the disk 405.

An example in which the number of power supply vias V located close to the noise wave source is 50 and the number of GND vias G located close to the noise wave source is 50 is described below. In the second example, when 20 inductance matrices are to be each calculated for 5 vias, the number of inductance elements defined in the model data on the vias is 300. On the other hand, when a single inductance matrix of all the vias is to be calculated, the number of inductance elements defined in the model data on the vias is 5050, and a period of time for the analysis is 282 times longer than a period of time for the analysis according to the second example.

[Example of Procedure for Analysis Support Process to be Executed by Analysis Supporting Device 100 According to Second Example]

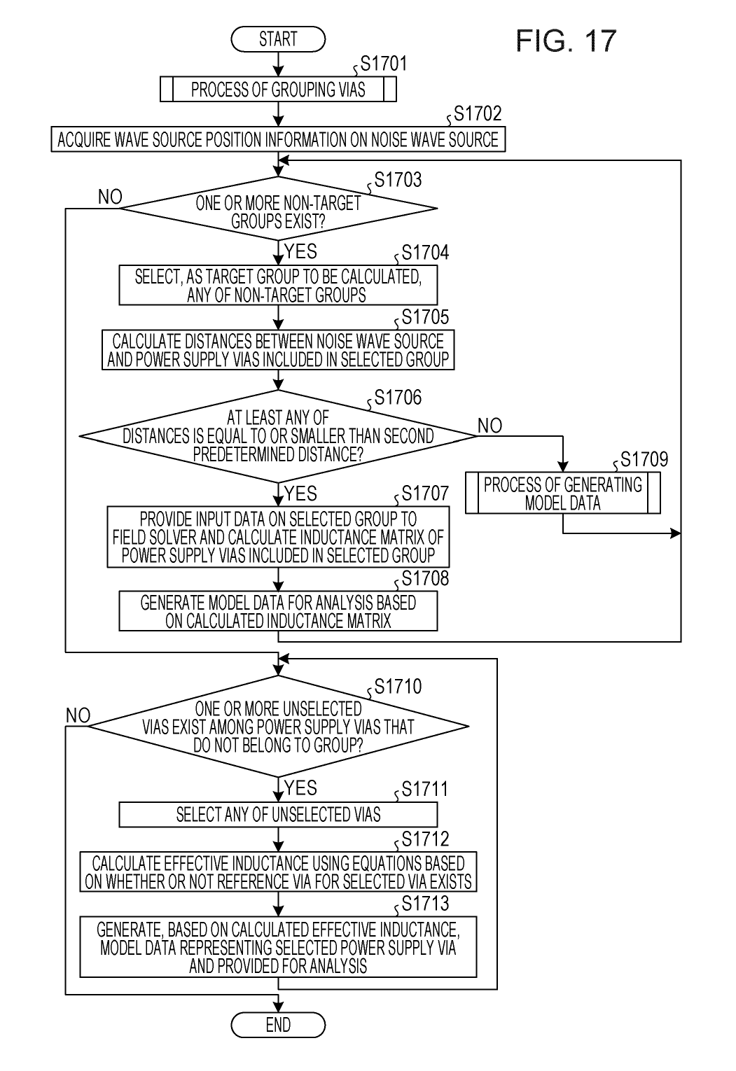

FIG. 17 is a flowchart of an example of a procedure for the analysis support process to be executed by the analysis supporting device according to the second example. In the example illustrated in FIG. 17, vias of the power supply via group are to be grouped, and vias of the GND via group are treated as reference vias. Thus, when vias of the GND via group are to be grouped and vias of the power supply via group are to be treated as reference vias, it is sufficient when the power supply vias V are interpreted as the GND vias G in the procedure, and the GND vias G are interpreted as the power supply vias V in the procedure. First, the analysis supporting device 100 executes the process of grouping vias (in step S1701). A detailed procedure for the process of grouping vias is the same as the procedure for the grouping process illustrated in FIGS. 14 and 15 in detail.

Next, the analysis supporting device 100 acquires the wave source position information 510 on the noise wave source (in step S1702). The analysis supporting device 100 determines whether or not one or more non-target groups exist (in step S1703). When the analysis supporting device 100 determines that the one or more non-target groups exist (Yes in step S1703), the analysis supporting device 100 selects any of the non-target groups as a group to be calculated (in step S1704). The analysis supporting device 100 calculates distances between the noise wave source and power supply vias V included in the selected group (in step S1705).

The analysis supporting device 100 determines whether or not at least any of the distances is equal to or smaller than the second predetermined distance T (in step S1706). When at least any of the distances is equal to or smaller than the second predetermined distance T (Yes in step S1706), the analysis supporting device 100 provides input data 511 on the selected group to the field solver and calculates an inductance matrix of the power supply vias V included in the selected group (in step S1707). Then, the analysis supporting device 100 generates model data 512 for the analysis based on the calculated inductance matrix (in step S1708) and causes the process to return to step S1703. When all the distances are not equal to or smaller than the second predetermined distance T (No in step S1706), the analysis supporting device 100 executes a process of generating model data (in step S1709) and causes the process to return to step S1703.

When the analysis supporting device 100 determines that a non-target group does not exist (No in step S1703), the analysis supporting device 100 causes the process to proceed to step S1710. Steps S1710 to S1713 are the same as steps S1306 to S1309, and a detailed description thereof is omitted.

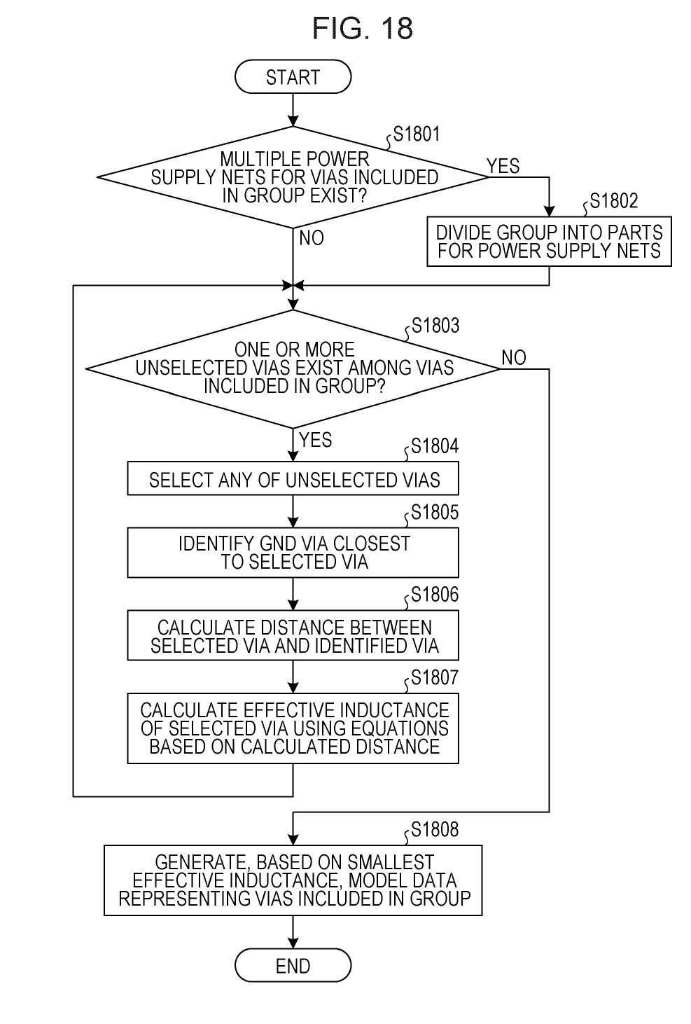

FIG. 18 is a flowchart of an example of a procedure for the process of generating model data. First, the analysis supporting device 100 determines whether or not multiple power supply nets for the vias included in the group exist (in step S1801). The multiple power supply nets indicate multiple power supply voltages. When the multiple power supply nets for the vias included in the group exist (Yes in step S1801), the analysis supporting device 100 divides the group into parts for the power supply nets (in step S1802) and causes the process to proceed to step S1803.

When the analysis supporting device 100 determines that the number of the power supply nets for the vias included in the group is less than two (No in step S1801), the analysis supporting device 100 determines whether or not one or more unselected vias exist among the vias included in the group (in step S1803). When the analysis supporting device 100 determines that the one or more unselected vias exist among the vias included in the group (Yes in step S1803), the analysis supporting device 100 selects any of the unselected vias (in step S1804). The analysis supporting device 100 identifies a GND via G located closest to the selected via (in step S1805). Then, the analysis supporting device 100 calculates a distance between the selected via and the identified via (in step S1806). The analysis supporting device 100 calculates, based on the calculated distance, an effective inductance of the selected via according to the equations (in step S1807) and causes the process to return to step S1803. The equations used in step S1807 are the aforementioned Equations (3) to (5).

When the analysis supporting device 100 determines that an unselected via does not exist (No in step S1803), the analysis supporting device 100 generates, based on the smallest effective inductance, model data 512 representing the vias included in the group (in step S1808) and terminates the process.

As described above, the analysis supporting device 100 identifies a second via having the second potential and located close to a first via of the first potential and identifies a third via having the first potential and located closer to the first via than the identified second via. Thus, vias that may have the same feedback path for a passing current may be grouped into the same group. Thus, only a mutual inductance between vias that may have the same feedback path for a passing current may be modeled. The accuracy of the analysis may be improved while the number of mutual inductances to be modeled is suppressed. In addition, since the number of mutual inductances is reduced, compared with a case where mutual inductances between all vias are to be modeled, a time period for the analysis may be reduced.

In addition, the analysis supporting device 100 identifies a second via that is included in the via group of the second potential and located closest to a first via and of which a distance from the first via is equal to or smaller than the predetermined distance. Thus, the via most likely to have a feedback path for a passing current may be identified.

Furthermore, the analysis supporting device 100 identifies a third via that is among the vias included in the via group of the first potential and is not the first via and of which a distance from the first via is equal to or smaller than a distance between the second via and the first via. Thus, all third vias for which the second via is used as a feedback path in the same manner as the first via may be identified.

Furthermore, the analysis supporting device 100 calculates an inductance matrix of the first and third vias and generates model data based on the inductance matrix. Thus, model data is obtained by modeling a mutual inductance of vias that may have the same feedback path for a passing current.

Furthermore, the analysis supporting device 100 generates model data based on the smallest effective inductance among a group located far from the noise wave source. Thus, the number of inductances may be suppressed.

Furthermore, when the third via does not exist, the analysis supporting device 100 generates association information that represents an association of the first via with the second via. The analysis supporting device 100 may determine, based on the association information, that the third via that has the same feedback path does not exist.

Furthermore, the analysis supporting device 100 treats vias of the via group of the first potential as first vias and identifies second vias and third vias for the first vias. Thus, vias that have the same feedback path may be grouped into the same group.

Furthermore, the analysis supporting device 100 calculates an inductance matrix of vias included in a group and having the first potential and generates model data based on the calculated inductance matrix. Thus, model data may be obtained by modeling a mutual inductance between vias that may have the same feedback path for a passing current.

Furthermore, the analysis supporting device 100 calculates an effective inductance of a via that does not belong to any group and has the first potential. Thus, an inductance of a via of which a feedback path is not the same as any via may be modeled.

Furthermore, when the first potential is the power supply potential, the second potential is the ground potential. When the first potential is the ground potential, the second potential is the power supply potential.

The analysis support method described in the embodiment may be achieved by causing a computer such as a personal computer or a workstation to execute the prepared analysis support program. The analysis support program is stored in a computer-readable recording medium such as a magnetic disk, an optical disc, or a universal serial bus (USB) flash memory. The analysis support program is read from the recording medium by the computer and executed by the computer. The analysis support program may be distributed through the network NET such as the Internet.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A computer-readable recording medium having stored therein a program for causing a computer to execute an analysis support process comprising:
acquiring via information that represents positions of a plurality of vias of a first via group included in a circuit board, the plurality of vias of the first via group having a first potential and positions of a plurality of vias of a second via group included in the circuit board, the plurality of vias of the second via group having a second potential different from the first potential;
identifying, based on the acquired via information, second via that is included in the plurality of vias of the second via group, a first distance between the second vias and a first via included in the plurality of vias of the first via group being equal to or smaller than a certain distance;
identifying, based on the via information, a third via that is included in the first via group, the third via being different from the first via, a second distance between the third via and the first via being equal to or smaller than the first distance; and
generating association information that represents associations of the first via, the second via, and the third via.

2. The computer-readable recording medium according to claim 1,
wherein the identifying of the second via is to identify a via that is included in the second via group and located closest to the first via among vias included in the second via group, a distance between each of the vias and the first via being equal to or smaller than the certain distance.

3. The computer-readable recording medium according to claim 1, further comprising:
calculating a self-inductance of the first via, a self-inductance of the third via, and a mutual inductance between the first via and the third via based on the generated association information and the via information; and
generating, based on the calculated self-inductances and the calculated mutual inductance, information that represents the first via and the third via.

4. The computer-readable recording medium according to claim 3, further comprising:
acquiring wave source position information on a position of a noise wave source included in the circuit board;
determining, based on the generated association information, the via information, and the acquired wave source position information, whether or not at least one of a distance between the first via and the noise wave source and a distance between the third via and the noise wave source is equal to or smaller than a second certain distance;
inhibiting the calculating from being executed when the distances between the noise wave source and the first and third vias are not equal to or smaller than the second certain distance;
identifying, based on the via information, a via included in the second via group and located closest to the first via and a via included in the second via and located closest to the third via;
calculating an effective inductance of the first via based on a distance between the first via and the identified via located closest to the first via and calculating an effective inductance of the third via based on a distance between the third via and the identified via located closest to the third via; and
generating information representing the first via and the third via based on the smallest effective inductance among the calculated effective inductances.

5. The computer-readable recording medium according to claim 1, further comprising:
generating association information that represents an association of the first via with the second via when the third via does not exist.

6. The computer-readable recording medium according to claim 1,
wherein the vias included in the first via group are treated as first vias,
wherein the identifying of the second via is to identify second vias for the first vias,
wherein the identifying of the third via is to identify third vias for the first vias, and
wherein the generating of the association information is to generate association information of associations of the first vias, the identified second vias, and the identified third vias.

7. The computer-readable recording medium according to claim 6, further comprising:
calculating self-inductances of first vias associated with a target via included in the first via group and to be calculated, a self-inductance of the target via, and mutual inductances between the target via and the first associated vias based on the generated association information, the via information, and second vias included in the second via group and each associated with any of the target via and the detected first associated vias; and
generating, based on the calculated self-inductances and the calculated mutual inductances, information that represents the target via and the first associated vias.

8. The computer-readable recording medium according to claim 7, further comprising:
calculating an effective inductance of the target via based on distances between the target via and the second associated vias when the first associated vias do not exist and the second vias associated with the target via exist;
calculating the effective inductance of the target via when the second associated vias do not exist; and
generating, based on the calculated effective inductance, information that represents the target via.

9. The computer-readable recording medium according to claim 7, further comprising:
acquiring wave source position information that represents the position of a noise wave source included in the circuit board;
determining, based on the generated association information, the via information, and the wave source position information, whether or not at least any of a distance between the noise wave source and the target via and distances between the noise wave source and the first associated vias is equal to or smaller than a second predetermined distance;
inhibiting the calculating from being executed when the distance between the noise wave source and the target via and the distances between the noise wave source and the first associated vias are not equal to or smaller than the second predetermined distance;
identifying, based on the acquired via information, a via that is included in the second via group and located closest to each of the target via and the first associated vias;
calculating an effective inductance of the target via and effective inductances of the first associated vias based on distances from the target via and the first associated vias to the identified vias; and
generating, based on the smallest effective inductance among the calculated effective inductances, information that represents the target via and the first associated vias.

10. The computer-readable recording medium according to claim 1,
wherein the first potential is a power supply potential and the second potential is a ground potential.

11. The computer-readable recording medium according to claim 1, wherein the first potential is a ground potential and the second potential is a power supply potential.

12. An analysis support method for causing a computer to execute a process comprising:
acquiring via information that represents the positions of vias of a first via group included in a circuit board and having a first potential and the positions of vias of a second via group included in the circuit board and having a second potential different from the first potential;
identifying, based on the via information, a second via that is included in the second via group and of which a distance from a first via included in the first via group is equal to or smaller than a predetermined distance;
identifying, based on the via information, a third via that is included in the first via group and is not the first via and of which a distance from the first via is equal to or smaller than a distance between the identified second via and the first via; and
generating association information that represents associations of the first via, the second via, and the third via.

13. An analysis supporting device comprising:
a processor configured to
acquire via information that represents the positions of vias of a first via group included in a circuit board and having a first potential and the positions of vias of a second via group included in the circuit board and having a second potential different from the first potential,
identify, based on the via information, a second via that is included in the second via group and of which a distance from a first via included in the first via group is equal to or smaller than a predetermined distance,
identify, based on the via information, a third via that is included in the first via group and is not the first via and of which a distance from the first via is equal to or smaller than a distance between the identified second via and the first via, and
generate association information that represents associations of the first via, the second via, and the third via.
